(19) United States
(12) Patent Application Publication
(10) Pub. No.: US 2016/0251227 A1
(43) Pub. Date: Sep. 1, 2016

(54) SYNTHESIS OF SI-BASED NANO-MATERIALS USING LIQUID SILANES

(71) Applicant: NDSU RESEARCH FOUNDATION, Fargo, ND (US)

(72) Inventors: Guruvenket Srinivasan, Fargo, ND (US); Kenneth Anderson, Fargo, ND (US); Justin Hoey, Fargo, ND (US); Robert A. Sailer, West Fargo, ND (US)

(73) Assignee: NDSU RESEARCH FOUNDATION, Fargo, ND (US)

(21) Appl. No.: 15/061,512

(22) Filed: Mar. 4, 2016

Related U.S. Application Data
(63) Continuation of application No. PCT/US2014/055271, filed on Sep. 11, 2014.
(60) Provisional application No. 61/877,929, filed on Sep. 13, 2013.

(51) Int. Cl. C01B 33/021; C23C 16/06; C23C 16/24; C09K 11/59; C23C 16/448

(52) U.S. Cl. CPC C01B 33/021; C09K 11/59; C23C 16/4486; C23C 16/24; C23C 16/06

(57) ABSTRACT

An apparatus and non-vapor-pressure dependent methods of producing silicon particles such as nanoparticles (Si-NPs), quantum dots (Si-QDs) and Si-nanocrystals (Si-NCs) as well as particle embedded thin films are disclosed. Nano or micro scale droplets of a liquid silane composition are polymerized in a gas phase with heat or radiation to produce particles that are then collected. Droplets from a droplet generator pass through a flow channel with a reaction zone that is heated or irradiated to form the particles that are collected in a collector. The flow of droplets may be assisted with carrier or flow gases that may be heated. Liquid silane composition solutions may also include metal, non-metal or metalloid dopants and solvents. Particle surfaces can also be passivated or functionalized. Particles and droplets of liquid silane can also be co-deposited and heated to produce particle embedded thin films.

### CROSS-REFERENCE TO RELATED APPLICATIONS

This application is a 35 U.S.C. §111(a) continuation of PCT international application number PCT/US2014/055271 filed on Sep. 11, 2014, incorporated herein by reference in its entirety, which claims priority to, and the benefit of, U.S. provisional patent application Ser. No. 61/877,929 filed on Sep. 13, 2013, incorporated herein by reference in its entirety. Priority is claimed to each of the foregoing applications.

The above-referenced PCT international application was published as PCT International Publication No. WO 2015/038833 on Mar. 19, 2015, which publication is incorporated herein by reference in its entirety.

### STATEMENT REGARDING FEDERALLY SPONSORED RESEARCH OR DEVELOPMENT

This invention was made with Government support under DE-FC36-08GO88160 awarded by the United States Department of Energy. The Government has certain rights in the invention.

### INCORPORATION-BY-REFERENCE OF COMPUTER PROGRAM APPENDIX

Not Applicable

### BACKGROUND

1. Technical Field

This technology pertains generally to synthesis schemes and methods for producing silicon based nanostructures and materials, and more particularly to compositions and methods for the synthesis of silicon-based materials using aerosolization of liquid hydrosilane(s).

2. Background Discussion

The abundance, environmental inertness, and advanced process technologies that are characteristic of silicon (Si) make it an ideal candidate for photovoltaics, energy storage, biomedical and microelectronic applications. Nanostructures and thin layers of Si are widely used for the aforementioned applications. Silicon based thin films, nanostructures and other materials have been synthesized conventionally using low pressure processes such as LPCVD, PECVD, and PVD using gaseous silanes. Silicon nanostructures and thin films are generally obtained by cracking or decomposing gaseous silicon precursors such as mono, di- and tri-silanes (SiH₄, Si₂H₆, Si₃H₈) or silicon tetrachloride/fluoride with a suitable reducing atmosphere at elevated temperatures. The addition of plasma to this process helps to decrease the processing temperature and increase the efficient utilization of the precursor. The aforementioned Si and Si containing materials (nanostructures and films/layers) can be synthesized as amorphous, polycrystalline, nano-crystalline or in mixed phases depending on the process parameters. Alternatively, they can be obtained from physical vapor deposition methods such as magnetron sputtering and cathodic arc, etc.

Although silicon is an indirect band-gap semiconductor, it exhibits a direct band-gap when reduced to the size of a few nanometers (e.g. Si-quantum dots, Si-QDs). Furthermore, Si-QDs show photoluminescence (PL) with UV excitation where the emission can be tuned in the visible to far IR region. This emission is dependent on the size of the Si-QDs as well as the surface chemistry of the Si-QD. These properties of the Si-QD make them suitable as an absorbing material for solar cells, for example. The fluorescing properties of Si-QDs and their biocompatibility also make Si-QDs ideal candidates for biomedical applications. The electroluminescent properties of Si-QDs also make them suitable for display electronic devices like light emitting diodes.

Conventional synthesis schemes for Si-nanocrystals usually include a low temperature gas-phase plasma synthesis. The gas-phase plasma synthesis technique requires a vacuum, a gaseous silane precursor and an in-flight post-plasma treatment and/or chemical treatment such as hydrosilylation to passivate the surface of the Si-QDs. Surface passivation of the outer surfaces of Si-QDs is necessary to form a good dispersion in a solvent, to prevent agglomeration and to allow photoluminescence.

Accordingly, there is a need for a simple, low-cost, atmospheric pressure, continuous, and scalable process for the synthesis of silicon nanoparticles (Si-NPs), including (Si-QDs) or (Si-NCs). The technology described herein satisfies this need as well as others and is generally an improvement in the art.

### BRIEF SUMMARY

The technology described herein provides an apparatus and methods for producing silicon nanomaterials such as nanoparticles (Si-NPs) and smaller and crystalline materials including silicon quantum dots (Si-QDs) or Si-nanocrystals (Si-NCs), referred to collectively as “nanoparticles.” By diligently controlling the chemistry of the starting materials and the reaction conditions it is possible to control the nanostructure and morphology of the Si-NPs, Si-QDs or Si-NCs that are produced.

The silicon nano or micro scale structures that are produced can also be incorporated into the synthesis of thin films, preferably using direct injection or aerosolized injection of cyclohexasilane (CHS, Si₆H₁₂), cyclopentasilane (CPS, Si₅H₁₀) or other cyclic, linear, branched neat hydrosilane liquids or mixtures thereof. Low volatility liquid silanes are less hazardous than other silanes, due to their reduced vapor pressures, and are more easily stored in large quantities than their volatile or gaseous counterparts.

One embodiment of a synthesis apparatus utilizes: (i) a droplet generator such as an injector/aerosolizer/nebulizer to inject/aerosolize or assist in the vaporization of a liquid hydrosilane(s) containing composition(s)/precursor mixture; (ii) an optional carrier gas to direct the liquid stream, vapor or aerosol through (iii) a single or multiple component apparatus including flow channel(s), reaction zone(s), material collector(s) or a combination thereof. The reaction zone(s) in the apparatus may have an elevated temperature and/or electromagnetic radiation exposure or a combination of the two. The material collector of the apparatus may also employ a method for isolating the particles produced by the reaction zone that may utilize a grid/filter or liquid to collect the synthesized materials or their combinations.

Conventional methods of precursor delivery of liquid silanes in chemical vapor deposition (CVD) procedures use bubblers, generally at reduced pressure and/or elevated temperature. However, during the CVD process, liquid silane precursors may degrade or change composition resulting in differing vapor pressures and non-uniform delivery to a reaction zone. This may lead to inconsistencies in the synthesis rate and/or product composition. These issues are avoided in the technology described herein by directly injecting the liquid to the system with or without an atomizer. This liquid is not preferentially evaporated, and consistent properties will be maintained in the liquid throughout the synthesis process. In the present process, liquid silanes are injected or aerosolized and the droplets are transported to the reaction zone.

In one embodiment of the apparatus, a syringe pump is used to inject the precursor silane solution in the device at a defined rate. The injected precursor solution is converted to droplets of fine mist or aerosol that are directed to a hot-zone in a flow chamber that has one end that is connected to a particle collector. The chamber has a heating element that can create a hot-zone of controlled temperature in the chamber.

A second carrier gas source may be used to maintain the flow of droplets through the chamber. The secondary carrier gas can be controllably mixed with the precursor hydrosilane at any point between the injector and the hot-zone. In another embodiment, the second carrier gas or gases are pre-heated so that the injected hydrosilane (precursor)/atomized droplets are heated by the gas and the droplets may be vaporized partially or completely before entering the hot-zone.

The initial liquid silane solutions that are used in either the production of nanoparticles or the production of the thin films may optionally include one or more dopant materials. Preferred metal dopants include P, B, Sb, Bi, or As and non-metal or metalloid dopants including elements from group IIIA, IVA or VA.

Further, the aforementioned dopants can be introduced in the liquid hydrosilane composition, where it is solubilized and a single liquid source is used. The dopant can also be introduced as a separate source that can be a gas or a liquid. The dopant source can be a metal-organic or organometallic precursor to deliver the dopant atoms. The source of the dopant or dopants can be introduced to the droplets either prior to the hot-zone or after the hot-zone.

The size and surface characteristics of the silicon nanostructures such as (Si-NPs), (Si-QDs) or (Si-NCs) that are produced by the apparatus can be selected through the selection of the drop size, temperature and dimensions of the hot-zone, time of laser exposure or residence time in the hot zone, characteristics of the carrier gas or gases and the identity of the initial silane materials and solvents. For example, the morphology of the particles such as Si-QD dots that are produced can be determined by the selection of droplet size and precursor composition. Surface passivation of the quantum dots may take place in flight and can also take place within the bubbler with the use of a suitable passivating media. Accordingly, a wide variety of nano-scale particle structures can be produced ranging from carbon coated Si-NPs to hydrosilyated Si-QDs.

In another embodiment, an apparatus is provided for producing Si-nanostructures that are incorporated into thin films on a substrate. In this embodiment, the apparatus for producing nanostructure embedded thin films has two subsystems: one for producing Si-QD's or other particles and the second for producing thin films on a substrate. The nanoparticle/quantum dot producing subsystem has a source of liquid silane precursor and a carrier gas that is introduced into an atomizer. The liquid droplets that have emerged from the atomizer are directed through a reaction zone that converts the droplets to nano-scale particles such as quantum dots by heating or by irradiation. An additional flow gas or gases may be introduced to increase the vaporization of the liquid silane aerosol droplets during flight to further facilitate nanoparticle formation. The nanoparticles can be collected and separated by size or the whole range of particle sizes that are produced can be used.

The second subsystem is for thin film production. This subsystem of the apparatus preferably uses a flow of input gas or gases such as nitrogen, helium or argon from a source of gas to an atomizer or other type of droplet generator. A liquid silane solution is injected into the gas stream and atomized by the atomizer and the droplets form a film on the substrate.

Alternatively, nanoparticles that were produced previously can be introduced into the chamber with the droplets and co-deposited on a substrate to form a continuous film. In one embodiment, the chamber has a bottom that has channels, slots, ducts or a screen or mesh to provide spatial control over the deposition of droplets/vapor and particles onto the substrate. The bottom of the chamber may also have openings that form a selected pattern or design.

In one embodiment, the substrate is disposed on a hotplate or other heating element to transform the material disposed in the substrate to amorphous silicon to crystalline silicon materials. Laser irradiation may also be used to crystallize the silicon. Post deposition processing may also be performed by plasma annealing of the Si-particulate embedded film.

Accordingly, a simple, low-cost, atmospheric pressure, continuous, and scalable process for the synthesis of silicon nanoparticles (Si-NPs), (Si-QDs) or (Si-NCs) is presented.

An aspect of the technology is to provide a controllable platform for the deposition of Si-QD or other particles on embedded intrinsic and doped thin films.

According to another aspect of the technology, a method of fabrication of all-Si multi-junction solar cells by using atmospheric pressure processes which are adaptable to continuous manufacturing.

Another aspect of the technology is to provide an apparatus and method that integrates doped a-Si:H/nc-Si:H, intrinsic a-Si:H/nc-Si:H and stoichiometric SiNx:H deposition technologies with Si quantum dots.

Another aspect of the technology is to provide an apparatus for the generation of mixed phase materials via co-deposition that is inexpensive, straightforward, and scalable when compared to state-of-the-art methods such as modified plasma enhanced chemical vapor deposition (PECVD), molecular beam epitaxy (MBE).

A further aspect of the technology is to provide an apparatus and method that is efficient, is not dependent on toxic gases, and can be used with roll-to-roll fabrication techniques.

Further aspects of the technology described herein will be brought out in the following portions of the specification, wherein the detailed description is for the purpose of fully disclosing preferred embodiments of the technology described herein without placing limitations thereon.

### BRIEF DESCRIPTION OF THE SEVERAL VIEWS OF THE DRAWINGS

The technology described herein will be more fully understood by reference to the following drawings which are for illustrative purposes only:

FIG. 1 is a flow diagram of one process for forming silicon nanoparticles such as quantum dots according to one embodiment of the technology described herein.

FIG. 2A is a schematic representation of an apparatus for aerosol assisted atmospheric pressure chemical vapor deposition with nanoparticle production according to one embodiment of the technology described herein.

FIG. 2B is a detail view of the heater and hot zone within the box shown in FIG. 2A.

FIG. 3 is a flow diagram of one process for forming silicon nanostructures with incorporated nanoparticles according to one embodiment of the technology described herein.

FIG. 4 is a schematic representation of an apparatus for aerosol assisted atmospheric pressure chemical vapor deposition with nanoparticle production according to one embodiment of the technology described herein.

### DETAILED DESCRIPTION

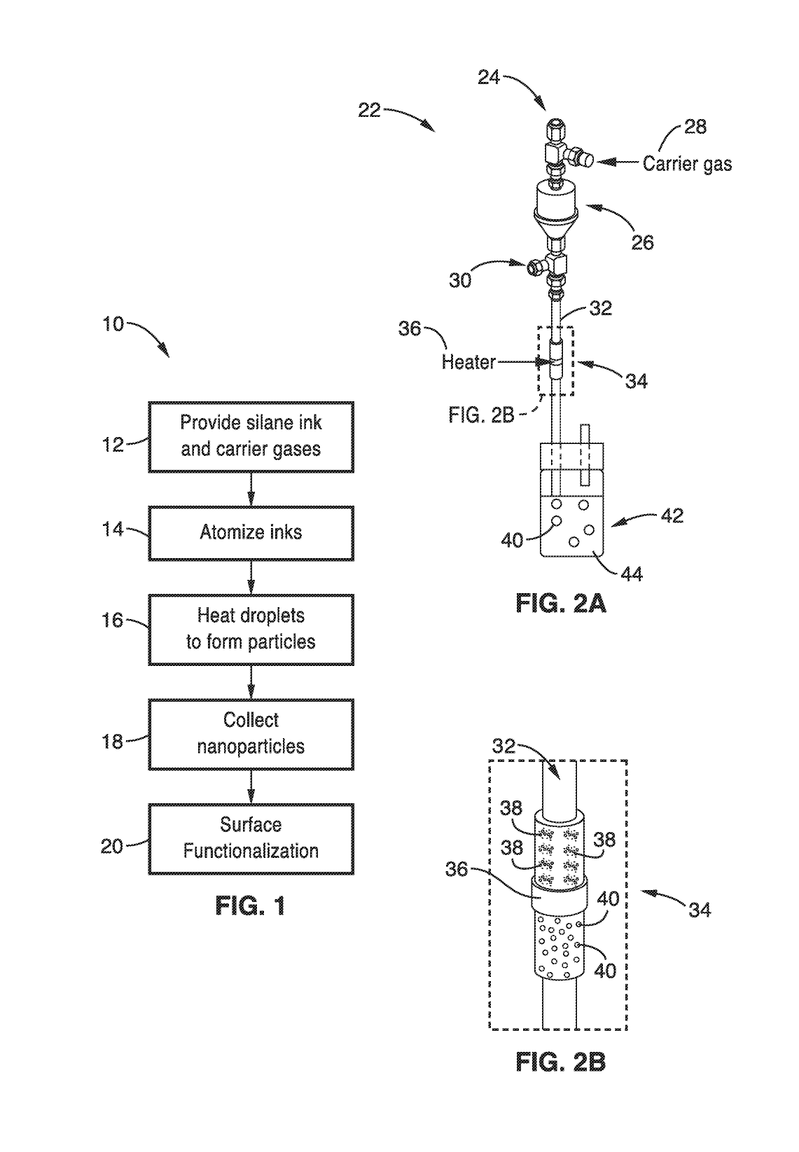

Referring more specifically to the drawings, for illustrative purposes, embodiments of the apparatus and methods for producing Si thin films using atomized liquid silane compositions of the technology described herein are described and depicted generally in FIG. 1 through FIG. 4. It will be appreciated that the methods may vary as to the specific steps and sequence and the apparatus may vary as to structural details without departing from the basic concepts as disclosed herein. The method steps are merely exemplary of the order that these steps may occur. The steps may occur in any order that is desired, such that it still performs the goals of the claimed technology.

Turning now to FIG. 1, a flow diagram of one embodiment of a method 10 for producing nano-scale silicon structures is set forth. The method, illustrated by steps 12 through 20, is for the production of silicon nanoparticles that may be collected and segregated according to size and the segregated nanoparticles may be used at a later time.

At block 12 of method 10, liquid silane precursor inks and carrier gases are selected and acquired. The liquid silane precursor inks can also include an organic solvent. The liquid silane composition at block 12 can contain a linear, cyclic, branched, oligomeric or polymeric hydrosilane or a combination of liquid silanes. Cyclohexasilane (Si₆H₁₂), cyclopentasilane, (Si₅H₁₀) and linear or branched liquid silanes (i.e., SiₙH₂ₙ₊₂) and combinations thereof are particularly preferred as a base silane precursor for producing nanoparticles.

The silane composition at block 12 can also be a heteroatom substituted silane or contain a chemical species with elements other than Si. Typical heteroatoms replacing carbons in the precursor structure include nitrogen, oxygen, sulfur, phosphorus, chlorine, bromine, and iodine. The liquid silane compositions may also contain a chemical species from group III and IV elements or metal or non-metal metalloid elements.

In another embodiment, a metal, non-metal or metalloid dopant is added to the composition of silane or silanes at block 12. Preferred metal dopants include P, B, Sb, Bi, or As and typical non-metal or metalloid dopants include elements from group IIIA, IVA or VA. Preferred dopants are elements or combinations of elements from the group including: Ti, V, Cr Mn, Fe, Co, Ni, Zn, Ga, Ge, As, Zr, Nb, Mo, Tc, Ru, Rh, Pd, Ag, Cd, In, Sn, Sb, Hf, Ta, W, Re, Os, Ir, Pt, Au, Hg, Tl, Pb, Bi, Al, P, and B.

Further, the aforementioned dopants can be introduced in the liquid hydrosilane composition, where it is solubilized and a single liquid source is used. The dopant can also be introduced as a separate source that can be a gas or a liquid. The dopant source can also be a metal-organic or organometallic precursor to deliver the dopant atoms. The dopant source can also be introduced either prior to the hot-zone or after the hot-zone.

The liquid silane composition provided at block 12 of FIG. 1 may also include one or more organic or metalorganic solvents. Preferred solvents that may be mixed with the liquid silane precursor to form the precursor ink include toluene, hexane, 1-dodecene, 1-octadecene and decaborane and mixtures thereof.

Carrier gases that are selected at block 12 are typically chemically inert gases such as nitrogen, argon or helium. In one embodiment, the carrier gas can chemically react with the silane droplets.

The liquid(s) and carrier gases may be injected simultaneously or individually or sequentially into an atomizer or other droplet generating device that is capable of producing nano-scale or micro-scale droplets at block 14 of FIG. 1. The droplets are carried away from the atomizer with the outflow of the carrier gas from the droplet producing device. The volume of carrier gas that is introduced to create a flow can be regulated to control the rate of droplet flow through the apparatus.

The size of the droplets can be regulated by the droplet generator at block 14 to provide some control over the size of the particles that are produced by the apparatus. Comparatively larger droplets will ultimately produce larger particles.

The droplets are heated or irradiated with laser light at block 16 of FIG. 1 to facilitate the conversion of the droplets to particles. The temperature and duration of the exposure of the droplets can be controlled to produce particles with the desired morphology and surface characteristics. The conversion of the droplets to solid particles can also be the result of multiple exposures with different temperatures and durations at block 16 of FIG. 1.

At block 18 of FIG. 1, the produced nanoparticles are collected by any suitable collection schemes. For example, the nanoparticles can be collected on a glass frit, a filter, a heated plate or with a bubbler.

Optionally, further surface functionalization or passivation of dangling Si bonds can be performed at block 20 of FIG. 1 to prepare the collected particles for specific uses.

An apparatus 22 for producing and collecting nanostructures such as (Si-NPs), (Si-QDs) or (Si-NCs) is schematically shown in FIG. 2A and FIG. 2B. In this embodiment of the apparatus, the prepared liquid silane composition is introduced through an injection port 24 to a droplet generator 26 such as an aerosolizer, atomizer, or nebulizer. The liquid silane compositions may be injected through port 24 by a controllable mechanical injector such as a syringe or other pump to meter the rate and volume of liquid silane material that is presented to the droplet producing component 26. The injection of materials may be continuous, sequential or intermittent.

The liquid silane compositions that are injected can go through the droplet generator 26 to form liquid droplets suspended in a gas in a controllable, non-vapor-pressure dependent way. The droplet generator 26 can be ultrasonic, pneumatic, mechanical, electrostatic or combinations thereof that may function individually and/or simultaneously, in-series or in combination.

The production of the suspension of droplets may also involve the addition of flowing gases such as a carrier gas 28. Carrier gas 28 may be injected with the liquid silane simultaneously, individually, or sequentially with the liquid silane. Carrier gas or gases 28 that are introduced with a liquid silane composition are typically chemically inert gases such as nitrogen, argon or helium. However, reactive gases may also be used alone or in combination with other gases as a carrier gas 28.

An optional flow gas 30 may be introduced after the droplets are produced by the droplet generator 26 to facilitate the flow of droplets through the chamber 32 and to control the rate of droplet flow. The direct gas injection of carrier gas 28 or flow gas 30 may be continuous, sequential or intermittent.

The flow gas 30 is an inert gas for most applications. However, in other applications, the flow gas 30 is a reactive gas that may participate in particle formation or in-flight particle passivation or functionalization.

The carrier gas 28 or the flow gas 30 may optionally be heated to a temperature above ambient temperature to increase the temperature of the droplets before they pass through the hot-zone 34 of chamber 32. Pre-heating the droplets with heated flow gases 30 or carrier gases 28 may also allow for the initial evaporation of solvents and reduce the droplet hot-zone 34 exposure times.

The embodiment shown in FIG. 2B has a single hot-zone 34 that has a heating element 36 and temperature monitor. However, multiple hot-zones may be used at different positions along the length of chamber 32. The hot-zone 34 of chamber 32 may also have an increased diameter and volume over the chamber dimensions. The temperature, diameter, volume and length of the hot-zone 34, as well as the droplet flow rate, can be tuned to provide conditions and residence times to convert the droplets 38 to particles 40. The temperatures that are provided in each hot-zone 34 are usually selected based on the characteristics of the liquid silane, droplet size, the solvent (if any), and the desired particle features. However, the preferred temperature in the hot-zone 34 ranges from between 400° C. and 1000° C.

In another embodiment, the hot-zone 34 is created with laser light of a suitable wavelength, energy and duration to allow the formation of the particles 40 from the droplets 38.

The formed particles 40 are then collected from chamber 32. A bubbler 42 is used in the embodiment shown in FIG. 2A. The media 44 of the bubbler 42 can be selected based on the surface characteristics of the emerging particles 40. A solvent such as toluene or chloroform is a preferred media 44 for the bubbler 42.

In another embodiment, the collection media 44 of the bubbler 42 includes a material that will passivate or functionalize the surfaces of the particles 40.

Although a bubbler 42 collector is shown in the illustration of FIG. 2A, other particle collection schemes such as glass frit paper or filtration can be used to collect and separate the particles.

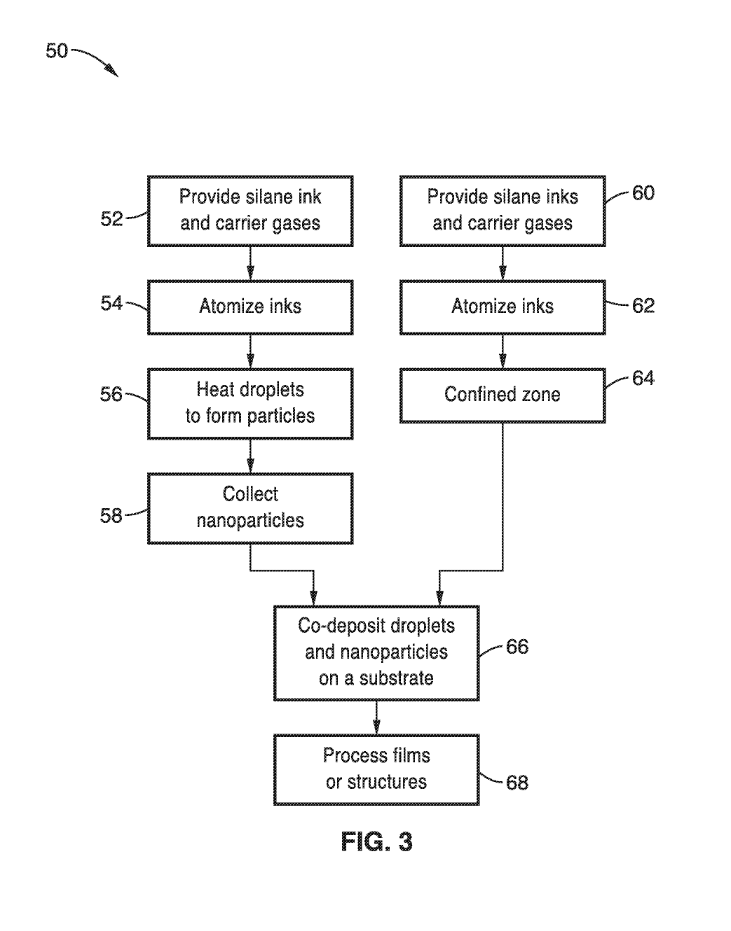

Referring now to FIG. 3, a flow diagram of one embodiment of a method 50 for producing aerosol assisted deposition of Si thin films with incorporated Si-nanostructures is schematically shown. In this embodiment, the method employs two independent subsystems. The first subsystem, represented by steps 52 through 58, is for the production of silicon nanoparticles that may be collected and segregated according to size and the segregated nanoparticles may be used at a later time. Alternatively, all of the continuously produced particles may be used at the same time as well.

The second subsystem, represented by steps 60 through 68, is for the production of the Si thin films. The embodiment shown in FIG. 3 has both subsystems working simultaneously, although the subsystems can work sequentially as well.

At block 52 of FIG. 3, liquid silane inks are identified and an inert carrier gas or gases are selected. Cyclohexasilane (Si₆H₁₂), cyclopentasilane, (Si₅H₁₀) and linear or branched silanes (i.e., SiₙH₂ₙ₊₂) are particularly preferred as a base silane precursor ink for producing nanoparticles. In one embodiment, dopants or other active materials such as metals, metalloids, alloys, oxides, or nitrides are added to produce modified Si nanoparticles. Solvents may also be added to the liquid silanes to produce the final silane precursor composition at block 52. Liquid silane compositions with organic solvents such as hexane, toluene, or metalorganic solvents are particularly preferred. Carrier gases such as nitrogen, argon or helium may also be selected at block 52.

At block 54, the selected liquid silane precursor composition is atomized to produce microdroplets that are optionally carried away from the droplet generator with a flow of a flow gas or carrier gas. The volume of carrier gas introduced to create a flow can be regulated to control the rate of droplet flow. The size of the droplets produced at block 54 and the rate of droplet production can also be controlled at block 54.

The droplets are heated to a temperature and for a duration that will convert the liquid silane droplets to a solid at block 56 of FIG. 3. The preferred temperature ranges from between 400° C. and 1000° C. In one embodiment, the droplets can be exposed to laser light to form the particles at block 56.

The resulting nanoparticles that are produced at block 56 can be collected at block 58 and either used as a group or separated according to size if generally uniform nanoparticles are desired. In one embodiment, the whole spectrum of nanoparticle sizes that are produced at block 56 are used in the production of thin films. In another embodiment, the particles produced at block 56 are separated by size and only particles of a desired size are used and incorporated into the final films. The collected particle surfaces may also be passivated or functionalized as needed.

The second subsystem of the method 50 shown in FIG. 3 is configured to thin film production. Generally, the subsystem uses liquid silane precursor compositions to produce thin films on a substrate that incorporates Si-nanoparticles such as quantum dots into the film.

In the step at block 60, the liquid silane composition for forming thin films with desired characteristics and carrier gas or gases are selected and obtained. Selection of the liquid silane precursor will be influenced by the desired characteristics and final use of the films. The liquid silane composition selected at block 60 can also be the same silane as those selected for nanoparticle production at block 52.

Preferred liquid silanes are of formula SiₓH_{y} where x is from 3 to 20, and y is 2x or (2x+2). Liquid cyclosilanes (i.e., SiₙH₂ₙ) such as cyclohexasilane (Si₆H₁₂) or cyclopentasilane, (Si₅H₁₀) and linear or branched silanes (i.e., SiₙH₂ₙ₊₂) are particularly preferred as a base liquid silane composition. Mixed liquid silanes can also be used as the base silane precursor at block 60.

In another embodiment, the silane or silanes selected and acquired at block 60 also includes a metal, non-metal or metalloid dopant composition to give the final film certain characteristics. A wide variety of metal and non-metal dopant compositions can qualify. Dopant compositions can be used alone or in combination with one or more other dopant compositions.

Preferred metal dopants include P, B, Sb, Bi, or As and typical non-metal or metalloid dopants include elements from group IIIA, IVA or VA. In particular, metal, non-metal, or metalloid elements and combinations include Ti, V, Cr Mn, Fe, Co, Ni, Zn, Ga, Ge, As, Zr, Nb, Mo, Tc, Ru, Rh, Pd, Ag, Cd, In, Sn, Sb, Hf, Ta, W, Re, Os, Ir, Pt, Au, Hg, Tl, Pb, Bi, Al, P and B.

In one embodiment, the liquid hydrosilane composition at block 60 also contains one or more nanomaterials. Nanomaterials that are part of the liquid silane precursor composition are nano-scale objects with at least one dimension of length between 1 nm and 100 nm. The nanomaterials can be of any shape including but not limited to spherical, cylindrical, conical, and combinations thereof. The nanomaterial can be single-crystalline, polycrystalline, amorphous and combinations thereof.

In another embodiment, the nanoparticles that were collected at block 58 are dispersed in the liquid silane precursor composition.

Optionally, the liquid silane film precursor provided at block 60 of FIG. 3 can also include a solvent. The solvent may be a solid, liquid or gas, but preferably a liquid or gas. The solvent is defined as a material that dissolves a solute to form a solution without chemically changing the solute. Preferred solvents include cyclooctane, hexane and toluene. The selection of the solvent will be influenced by the selection of the silane and dopant for the final precursor composition.

Carrier or flow gases that are selected at block 60 are preferably inert gases that do not react with the liquid silane compositions or their reaction products. Preferred gases include N₂, He and Ar alone or in combination.

The silane film precursor selected at block 60 is aerosolized or atomized at block 62 of FIG. 3 to produce droplets that can be carried by carrier gases. In one embodiment, the silane precursor is injected into a stream of gas and directed through an atomizer nozzle.

The droplets that are produced by the droplet generator such as an atomizer at block 62 are optionally directed through at least one confined zone at block 64 of FIG. 3 for a preliminary treatment. The rate of flow of the droplets through the zone can be regulated. In one embodiment, the confined zone may include additional mechanism(s) to mix the contents in the zone including aerodynamic, acoustic, and mechanical mechanisms.

The confined zone(s) at block 64 can be of any shape and kept at any temperature or temperature distribution greater than, less than, or equal to that of the liquid silane compositions. In one embodiment, the confined zone is heated with a heating element to a range of temperatures.

In another embodiment, the carrier gases are heated or cooled so that the confined zone is also heated or cooled as the gases and droplets flow through. The temperature of the confined zone may be maintained at levels that result in the evaporation of solvents that may optionally be part of the liquid silane film precursor composition.

In another embodiment, carrier gases that are added to the liquid silane injection stream or to the produced liquid silane aerosol droplets can be inert, reactive or a combination of the two types of gases. The secondary carrier gas can contain a vapor of liquid, vapor of solid and combinations thereof from an additional precursor containing elements including Si.

At block 66, the liquid silane composition passes through the confined zone and is co-deposited with nanoparticles on a substrate. The collected nanoparticles at block 58 may also be introduced to the confined zone and mixed with the droplets flowing through the zone in one embodiment. In another embodiment, a carrier gas with nanoparticles is introduced to the droplet flow before or after the confined zone.

The liquid hydrosilane exiting the confined zone can be a vapor or aerosol (liquid in gas, solid in gas or combinations thereof). In one embodiment, the liquid hydrosilane composition droplets or vapor exiting the confined zone is transported through an exit channel. The exit channel can have a variety of different geometries including cylindrical, narrow-slit, shower-head type or combinations of openings. The bottom of the confined zone may also have a grid or mesh structure or a pattern. The bottom of the confined zone may also be heated or cooled or both.

The vapor or droplets of liquid silane composition exiting the confined zone are deposited on a substrate at block 66 to produce a film with a thickness that can be controlled by controlling the droplet size and rate of deposition. The droplets can also coat a structure or form nanostructures such as nanowires.

At block 68, the deposited droplet and nanoparticle material that has formed a film or other structure can be processed further to produce a final product. In one embodiment, the substrate is maintained at a temperature from 0° C. to 1200° C., preferably from 25° C. to 800° C. and most preferably from 300° C. to 600° C. In another embodiment, the substrate is traversed by the apparatus head at a given velocity to produce continuous silicon films with chosen properties. The velocity may be from approximately 1 to 1000 mm/second.

In a further embodiment, the deposited film on the substrate is first heated to a temperature of between about 300° C. to 500° C. for a period of time to produce amorphous silicon that is then exposed to laser irradiation for a second period of time to form crystalline silicon.

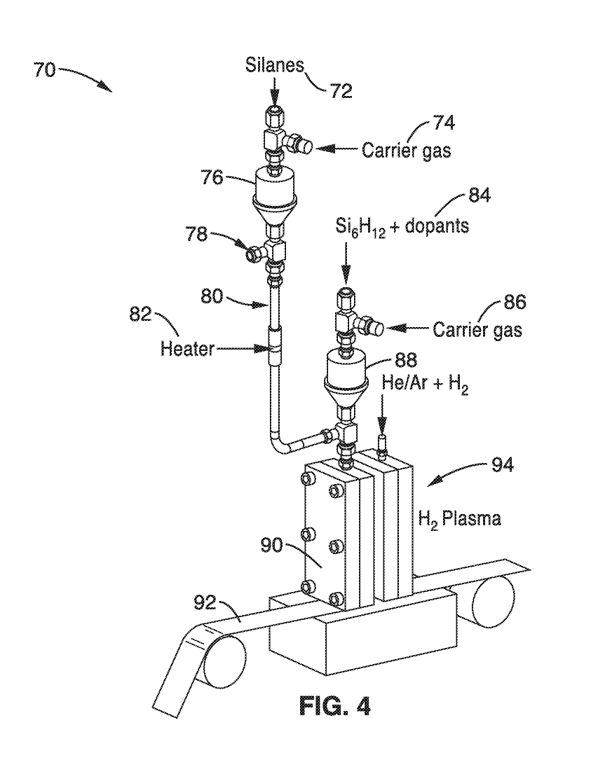

Turning now to FIG. 4, a representation of one embodiment 70 of an apparatus for forming silicon films with incorporated nanoparticles on a substrate is schematically shown. The apparatus 70 is configured for the continuous production of particles and particle embedded thin films.

Nano-scale particles with desired features are produced with the selection of a liquid silane composition and the general particle size. The selected liquid silane solution 72 is introduced with a carrier gas 74 to an droplet generator such as an atomizer 76 in the embodiment shown in FIG. 4. In an alternative embodiment, the atomizer 76 does not utilize carrier gases and an initial carrier gas is not used.

The atomizer 76 produces a vapor or mist of droplets from an output into the interior of a chamber 80. The size of the droplets that are produced by the atomizer 76 is preferably uniform and scalable. Droplet size will essentially determine the minimum size of the particles resulting from the process.

An optional flow gas 78 can be introduced into the chamber 80 through a valve to assist in vaporization and droplet flow through the chamber 80. The flow of droplets is then heated with a heater 82 that converts the droplets to silicon nanoparticles for incorporation into the final thin film.

As an example of this stage, silicon nanoparticles such a quantum dots can be produced by vaporizing a solution of an organic solvent and a liquid silane to produce nano/micro droplets of silane solution composition. The droplets are polymerized in a gas phase and heated to remove hydrogen gas to produce Si—H nanoparticles. The Si—H nanoparticles are capped by decomposing the organic solvent and then reacting the decomposed solvent with the Si—H nanoparticles.

The particles that are produced move through chamber 80 and are ultimately incorporated within a thin film that is deposited on a substrate. The thin film is produced beginning with the injection of a precursor solution of liquid silanes along with one or more optional dopants or optional solvents. The liquid silane composition 84 that is prepared is introduced by a syringe or pump with a carrier gas 86 to a second atomizer 88.

The droplets produced by the film atomizer 88 may be larger or smaller than those produced by the first atomizer 76 and the droplet size may be optimized for film formation. The feed rate of the precursor solution can be maintained at a constant or variable rate using a fluid injector pump or syringe (not shown) in one embodiment.

The film precursor atomizer 88 produces a flow of atomized droplets and a preliminary carrier gas 86 to a deposit head 90 that may have a chamber in the interior forming a confined zone and an output. In the embodiment shown in FIG. 4, a flow of nanoparticles and carrier/flow gas from chamber 80 is combined with the flow of carrier gas 86 and droplets from the second atomizer 88 that flow into the deposit head 90.

The silane droplets or vapor, nanoparticles and gases are then transported out of the head 90 and deposited on the substrate 92. The substrate 92 is a continuous roll of material that is advanced across the openings of head 90.

The deposit head 90 may optionally include a heating or cooling element so that the interior can be maintained at a desired temperature or to increase or decrease the temperature at the bottom of the head 90. The flow gas 74 and the carrier gases 78 and 86 may also be pre-heated or cooled from the source before introduction into the apparatus.

The deposited film on substrate 90 can also be subjected to additional post deposition treatments such as additional heating or laser treatments to produce the final film. In the embodiment shown in FIG. 4, the deposited film is annealed with plasma 94 as a post deposition treatment.

The technology described herein may be better understood with reference to the accompanying examples, which are intended for purposes of illustration only and should not be construed as in any sense limiting the scope of the technology described herein as defined in the claims appended hereto.

### Example 1

In order to demonstrate the operational principles of the apparatus and synthesis methods, an apparatus was constructed having the features shown schematically in FIG. 2. A liquid silane, CHS either in its pure form or diluted in a solvent (toluene), was controllably injected using a syringe pump into an ultrasonic horn atomizer (Sono-Tek Inc. Milton, N.Y.) operating at 120 kHz. Helium (He) at a flow rate of 300 sccm was flowed through the atomizer to carry the aerosol mist through a coupling and into a 0.5″ OD (10.2 mm ID) 316 stainless steel (SS) or quartz tube, 30 cm long. An electric resistance coil heater 51 mm long (Freek-Heaters GmbH, Germany) was placed over the outside of the tube below the atomizer. A glass fiber filter or liquid bubbler particle collector was placed at the end of the SS tube.

The entire apparatus was located inside an inert atmosphere (N₂, less than 1 ppm O₂) glovebox to preclude exposure of the CHS precursor, and Si-NPs to ambient oxygen and water.

The process temperature for these experiments was varied from 500° C. to 900° C. in 100° C. increments. The atomized silane that passes through the hot-zone first vaporizes, then nucleates into Si-NPs which are further collected either by using a bubbler filled with a solvent (toluene or chloroform or hexane or mesitylene-dodecene) or collected on glass frit paper.

A JEOL JEM-100CX II transmission electron microscope (TEM) and JEOL JSM-6490LV scanning electron microscope (SEM) were used to determine the surface morphology, structure and composition (energy dispersive X-ray analysis (EDS)) of the Si-NPs. In addition, a Veeco DI-3100 atomic force microscope (AFM) was used to determine the surface morphology. The surface chemistry of the Si-NPs was determined using nuclear magnetic resonance (NMR), and Fourier transform infrared spectroscopy (FTIR) using a Thermo Scientific Nicolet 8700 instrument. FTIR spectra were collected between 400 cm⁻¹ to 4000 cm⁻¹ with a 2 cm⁻¹ resolution. A total of 64 scans were performed per measurement to improve the signal-to-noise ratio.

Microstructural changes and crystallinity of the samples were determined by Raman Spectroscopy and X-ray diffraction (XRD) analyses. Ram Raman spectroscopic analysis was performed using a HORIBA Jobin Yvon LabRAM ARAMIS confocal imaging system with a 532 nm Nd:YAG laser and 100× objective, while XRD analyses were at grazing incidence of 2.0° using a Rigaku (Cu Kα radiation, λ=1.5406 Å). The Scherrer equation was used to determine the crystalline grain size with an instrumental broadening factor of 0.107 (FWHM).

Quantum yield (QY) was measured using an Ocean Optics USB2000 spectrometer equipped with an integrating sphere and a light-emitting diode with 375 nm emission was used as the source for excitation. Measured PL spectra from Si-QDs (that are dispersed in chloroform), was compared with spectra from neat chloroform to determine the QYs.

The temperature of synthesis had a greater influence on the characteristic color of the suspensions, samples synthesized Si-Nanoparticles. Samples synthesized at 500° C. were amorphous in nature, while the Si-NPs synthesized above were crystalline in nature.

SEM and TEM images of Si-NPs show no crystalline nature. EDS analysis of this sample showed no other elements other than Si. Raman spectroscopic analysis showed a peak at 493 cm⁻¹, which correspond to amorphous/nano-crystalline Si.

TEM images of the samples synthesized at 700° C. and 750° C., which exhibit different morphology with features and particles that range from less than 10 nm in size to particles that are larger than 100 nm in size.

The Si-QDs synthesized at and above 700° C. have crystalline Si particles. The large Si-NPs that are formed with a carbon shell can be beneficial to energy storage application in form of Li-ion battery anode materials.

Raman spectroscopic analysis of these Si-nanoparticles depict a crystalline peak at 518.94 cm⁻¹. Photoluminescence spectra of these Si-QDs emission around ˜605 nm. PL properties of the Si-QDs can be controlled by size of the Si-QDs and its surface chemistry.

### Example 2

To demonstrate the methods, Si-QD's were synthesized with pure-CHS at 760° C. using the horizontal reactor with the structure shown in FIG. 2. The Si-QDs were collected in the bubbler that was filled with a mixture of mesitylene and dodecene. Post-synthesis, this mixture was refluxed at 170° C. for 12 hours to hydrosilyliate the Si-QDs (ex-situ passivation).

In another embodiment, liquid silane was mixed with hexane and used as the precursor liquid. The Si-QDs were collected in a bubbler filled with hexane. The Si-QDs synthesized using this approach did not require post-passivation since the Si-QDs were passivated in-flight (in-situ).

The PL spectra of the Si-QDs synthesized with neat Si₆H₁₂ and Si-QDs (ex-situ and in-situ passivated) were acquired and evaluated. Unlike other conventional techniques this approach does not require a post-passivation process.

### Example 3

To further demonstrate the methods, Si-QD's were synthesized with a toluene-CHS silane composition at different temperatures and collected in a bubbler. The bubbler media was centrifuged and the supernatant was collected. The supernatant collected from the samples synthesized at 800° C. had a red-orange color while others were transparent. The 800° C. supernatant was filtered through 200 nm Teflon mesh and the collected Si-NPs were analyzed to determine the particle size surface morphology and their photo-luminescent properties.

TEM studies of samples that were collected in toluene media showed the presence of Si-nano-crystals (NCs) or Si-QDs. TEM images showed Si-QDs with different sizes that were generally smaller than 10 nm with a distribution in the particle size ranging from 1.5 nm to 20 nm. Magnified images of the larger particles, approximately 20 nm in diameter, also showed crystalline lattice planes. The d-spacing determined from the fringe spacing corresponded to a Si(100) lattice.

A photo-luminescence spectroscopic analysis was carried out using a 365 nm excitation source, where the Si-QDs that were suspended in toluene and contained in glass vial were studied. The observed PL emission peaks had a maximum intensity at 613 nm and 583 nm and 743 nm for supernatant-unfiltered, filtered supernatant and UMN reference samples respectively. The full-width at half maximum for the same samples was 144.4 nm and 142.6 nm and 150 nm respectively. Decreases in the emission peak position suggested the presence of smaller Si-QDs and a decrease in FWHM was an indication of narrow particle size distribution. It appears that Si-QDs from CHS that were filtered may contain smaller Si-NCs and their size distribution could be minimal. The presence of higher molecular weight hydrocarbon that is formed from toluene decomposition can also exhibit PL but at much lower wavelength.

### Example 4

The utility of large Si-NPs that are formed with a carbon shell for use with energy storage applications in the form of Li-ion battery anode materials was tested. The Si-NPs were mixed with acetylene black, PVDF and NMP vigorously mixed to make a slurry. About 40 μl of the slurry was then dispensed on Cu foil (2 cm dia) and the let the solvents to evaporate slowly followed by a thermal treatment at 180° C. for 12 hours.

Coin cells were fabricated with Cu foil coated with Si-NPs used as the anode, Li foil cathode, standard LiPF₆ used as the electrolyte and PE porous membrane spacer between anode and the cathode. Electrochemical performances of the half-cells were performed using an Arbin tester, where the charge and discharge rates were determined from the mass of Si-NPs (assuming 4200 mAh/g capacity for Si).

### Example 5

The simple integration scheme shown in FIG. 3 and FIG. 4 provides a controllable platform for the deposition and formation of intrinsic, doped particle embedded materials. For example, the apparatus and process can integrate doped a-Si:H/nc-Si:H, intrinsic a-Si:H/nc-Si:H and stoichiometric SiNx:H deposition technologies with Si quantum dot (Si-QD) synthesis to produce hybrid multi-junction PV devices.

Aerosol assisted atmospheric pressure chemical vapor deposition (AA-APCVD) of thin films from cyclohexasilane (CHS) was shown to provide near device quality intrinsic and doped a-Si:H/nc-Si:H at notably high deposition efficiencies and growth rates. The deposition parameters with respect to microstructure, band-gap energy, and carrier mobility for a-Si:H, nc-Si:H, and Si-QD embedded mixed phase materials can also be optimized.

Co-deposition of Si-QDs and matrix materials (a-Si:H, SiNx:H) at atmospheric pressure can also be used to generate mixed phase photon absorbers for 3rd generation all Si solar cells. The apparatus allows for optimization of Si-QD size and concentration (AA-APCVS) independent of thin film growth (AA-APCVD) parameters, avoiding the limitations seen in alternative processes in the art.

The generation of mixed phase materials produced via co-deposition are inexpensive, straightforward, and scalable when compared to state-of-the-art methods such as modified plasma enhanced chemical vapor deposition (PECVD), molecular beam epitaxy (MBE), and high temperature phase segregation of straited dielectric/silicon-rich dielectric layers.

From the description herein, it will be appreciated that the present disclosure encompasses multiple embodiments which include, but are not limited to, the following:

1. An apparatus for synthesizing Si particles, comprising: a source of a liquid silane solution; a droplet generator coupled to the source configured to produce nano or micro scale droplets of solution from the source of liquid silane solution; a flow channel with a central bore and a reaction zone; a heating element for heating the reaction zone of the flow channel; and a particle collector proximal to the bore of the flow channel; wherein droplets moving through the reaction zone of the flow channel are converted to particles that are collected by the particle collector.

2. The apparatus of any preceding embodiment, further comprising: a source of a carrier gas operably coupled to the droplet generator.

3. The apparatus of any preceding embodiment, the flow channel further comprising: one or more input ducts coupled to a source of at least one flow gas, the input ducts introducing a flow of gas through the bore of the flow channel from the source of flow gas.

4. The apparatus of any preceding embodiment, further comprising: a flow gas heater; wherein the flow gas is heated to a temperature above ambient temperature before flowing through the bore of the flow channel.

5. The apparatus of any preceding embodiment, wherein the heating element comprises a laser configured to irradiate the reaction zone with laser light.

6. The apparatus of any preceding embodiment, wherein the heating element comprises: a heater; and a laser configured to irradiate the reaction zone with laser light.

7. The apparatus of any preceding embodiment, wherein the heating element comprises a thermocouple configured to heat the reaction zone to a temperature ranging from approximately 600° C. and 1000° C.

8. The apparatus of any preceding embodiment, wherein the particle collector is a collector selected from the group consisting of a glass frit, a filter, a heated plate and a bubbler.

9. A method for producing silicon nanoparticles, comprising: forming droplets of a liquid silane composition; polymerizing the droplets in a gas phase to produce nanoparticles with heat, laser irradiation or both; and collecting the polymerized nanoparticles.

10. The method of any preceding embodiment, further comprising functionalizing outer surfaces of the collected nanoparticles.

11. The method of any preceding embodiment, wherein the liquid silane composition comprises a silane selected from the group of silanes consisting of a linear, cyclic, branched, oligomeric and polymeric hydrosilanes and mixtures thereof.

12. The method of any preceding embodiment, wherein the liquid silane composition is a silane selected from the group of silanes consisting of cyclopentasilane (CPS), neopentasilane (NPS), and cyclohexasilane (CHS) and mixtures thereof.

13. The method of any preceding embodiment, wherein the liquid silane composition contains a heteroatom substituted silane.

14. The method of any preceding embodiment, wherein the liquid silane composition comprises: at least one liquid silane; and a dopant.

15. The method of any preceding embodiment, wherein the dopant is a metal dopant selected from the group of dopants consisting of P, B, Sb, Bi, and As.

16. The method of any preceding embodiment, wherein the dopant is a non-metal or metalloid dopant selected from the group consisting of elements of Group IIIA, IVA and VA.

17. The method of any preceding embodiment, wherein the liquid silane composition comprises at least one liquid silane; and at least one solvent.

18. The method of any preceding embodiment, wherein the solvent is a solvent selected from the group of solvents consisting of hexane, toluene, cyclooctane, 1-dodecene, 1-octadecene and decaborane and mixtures thereof.

19. The method of any preceding embodiment, further comprising: heating the droplets to remove hydrogen gas to produce Si—H nanoparticles; and capping the Si—H nanoparticles by decomposing the solvent with heat or radiation and reacting the decomposed solvent with the Si—H nanoparticles.

20. An apparatus for synthesizing silicon thin films with embedded Si nanoparticles or quantum dots, comprising: a source of a liquid silane solution; a droplet generator coupled to the source configured to produce nano or micro scale droplets of liquid silane solution from the source of liquid silane solution; a housing with an interior chamber coupled to an output of the droplet generator and at least one film output duct; and a source of nanoparticles coupled to the housing; wherein liquid silane droplets and nanoparticles are emitted from the output ducts and of the housing and co-deposited on a substrate.

21. The apparatus of any preceding embodiment, further comprising a heating element for heating the deposited droplets and nanoparticles on the substrate.

22. The apparatus of any preceding embodiment, wherein the heating element comprises a plasma heater.

23. The apparatus of any preceding embodiment, further comprising a source of at least one carrier gas coupled to the housing configured to produce a controlled flow of carrier gas, droplets and particles through the housing and out of the housing output duct.

24. The apparatus of any preceding embodiment, wherein the source of carrier gas is heated to a temperature above ambient temperature.

25. The apparatus of any preceding embodiment, wherein source of nanoparticles comprises: a source of a liquid silane solution; a droplet generator coupled to the source configured to produce nano or micro scale droplets of solution from the source of liquid silane solution; a flow channel with a central bore and a reaction zone; a heating element for heating the reaction zone of the flow channel; and an input duct coupled to the housing; wherein droplets moving through the reaction zone of the flow channel are converted to nanoparticles; and wherein produced nanoparticles are introduced into interior chamber of the housing through the input duct to be co-deposited on a substrate.

26. A method for synthesizing silicon thin films with embedded Si nanoparticles or quantum dots, comprising: producing a plurality of nanoparticles; forming droplets of a liquid silane film composition; co-depositing the droplets and nanoparticles onto a substrate to form a film; and heating the deposited film.

27. The method of any preceding embodiment, wherein the liquid silane film composition comprises: at least one liquid silane; and at least one solvent.

28. The method of any preceding embodiment, wherein the liquid silane is a silane selected from the group of silanes consisting of cyclopentasilane (CPS), neopentasilane (NPS), and cyclohexasilane (CHS) and mixtures thereof.

29. The method of any preceding embodiment, wherein the solvent selected from the group of solvents consisting of cyclooctane, hexane and toluene.

30. The method of any preceding embodiment, wherein the liquid silane film composition comprises: at least one liquid silane; at least one solvent; and at least one dopant.

31. The method of any preceding embodiment, wherein the dopant is a metal dopant selected from the group of dopants consisting of P, B, Sb, Bi, and As.

32. The method of any preceding embodiment, wherein the dopant comprises an element selected from the group of elements consisting of Ti, V, Cr Mn, Fe, Co, Ni, Zn, Ga, Ge, Zr, Nb, Mo, Tc, Ru, Rh, Pd, Ag, Cd, In, Sn, Hf, Ta, W, Re, Os, Ir, Pt, Au, Hg, Tl, Pb, Bi and Al.

33. The method of any preceding embodiment, wherein the nanoparticles are produced by the process, comprising: forming droplets of a liquid silane composition; polymerizing the droplets in a gas phase to produce nanoparticles with heat, laser irradiation or both; and collecting the polymerized nanoparticles.

Although the description herein contains many details, these should not be construed as limiting the scope of the disclosure but as merely providing illustrations of some of the presently preferred embodiments. Therefore, it will be appreciated that the scope of the disclosure fully encompasses other embodiments which may become obvious to those skilled in the art.

In the claims, reference to an element in the singular is not intended to mean “one and only one” unless explicitly so stated, but rather “one or more.” All structural, chemical, and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

What is claimed is:

1. An apparatus for synthesizing Si particles, comprising:
a source of a liquid silane solution;
a droplet generator coupled to the source configured to produce nano or micro scale droplets of solution from the source of liquid silane solution;
a flow channel with a central bore and a reaction zone;
a heating element for heating the reaction zone of the flow channel; and
a particle collector proximal to the bore of the flow channel;
wherein droplets moving through the reaction zone of the flow channel are converted to particles that are collected by the particle collector.

2. The apparatus of claim 1, further comprising a source of a carrier gas operably coupled to the droplet generator.

3. The apparatus of claim 1, said flow channel further comprising:
one or more input ducts coupled to a source of at least one flow gas;
the input ducts introducing a flow of gas through the bore of the flow channel from the source of flow gas.

4. The apparatus of claim 3, further comprising:
a flow gas heater;
wherein said flow gas is heated to a temperature above ambient temperature before flowing through the bore of the flow channel.

5. The apparatus of claim 1, wherein said heating element comprises a laser configured to irradiate the reaction zone with laser light.

6. The apparatus of claim 1, wherein said heating element comprises:
a heater; and
a laser configured to irradiate the reaction zone with laser light.

7. The apparatus of claim 1, wherein said heating element comprises a thermocouple configured to heat the reaction zone to a temperature ranging from approximately 600° C. to 1000° C.

8. The apparatus of claim 1, wherein said particle collector is a collector selected from the group consisting of a glass frit, a filter, a heated plate and a bubbler.

9. A method for producing silicon particles, comprising:
forming droplets of a liquid silane composition;
polymerizing the droplets in a gas phase to produce nanoparticles with heat, laser irradiation or both; and
collecting the polymerized nanoparticles.

10. The method of claim 9, further comprising functionalizing outer surfaces of said collected nanoparticles.

11. The method of claim 9, wherein said liquid silane composition comprises a silane selected from the group of silanes consisting of a linear, cyclic, branched, oligomeric and polymeric hydrosilanes and mixtures thereof.

12. The method of claim 9, wherein said liquid silane composition is a silane selected from the group of silanes consisting of cyclopentasilane (CPS), neopentasilane (NPS), and cyclohexasilane (CHS) and mixtures thereof.

13. The method of claim 9, wherein said liquid silane composition contains a heteroatom substituted silane.

14. The method of claim 9, wherein said liquid silane composition comprises:
at least one liquid silane; and
a dopant.

15. The method of claim 14, wherein said dopant is a metal dopant selected from the group of dopants consisting of P, B, Sb, Bi, and As.

16. The method of claim 14, wherein said dopant is a non-metal or metalloid dopant selected from the group consisting of elements of Group IIIA, IVA and VA.

17. The method of claim 9, wherein said liquid silane composition comprises:
at least one liquid silane; and
at least one solvent.

18. The method of claim 17, wherein said solvent is a solvent selected from the group of solvents consisting of hexane, toluene, cyclooctane, 1-dodecene, 1-octadecene and decaborane and mixtures thereof.

19. The method of claim 17, further comprising:
heating the droplets to remove hydrogen gas to produce Si—H nanoparticles; and
capping the Si—H nanoparticles by decomposing the solvent with heat or radiation and reacting the decomposed solvent with the Si—H nanoparticles.

20. An apparatus for synthesizing silicon thin films with embedded Si particles, comprising:
a source of a liquid silane solution;
a droplet generator coupled to the source configured to produce nano or micro scale droplets of liquid silane solution from the source of liquid silane solution;
a housing with an interior chamber coupled to an output of the droplet generator and at least one film output duct; and
a source of nanoparticles coupled to the housing;
wherein liquid silane droplets and nanoparticles are emitted from the output ducts and of the housing and co-deposited on a substrate.

21. The apparatus of claim 20, further comprising a heating element for heating the deposited droplets and nanoparticles on the substrate.

22. The apparatus of claim 21, wherein said heating element comprises a plasma heater.

23. The apparatus of claim 20, further comprising a source of at least one carrier gas coupled to the housing configured to produce a controlled flow of carrier gas, droplets and particles through the housing and out of the housing output duct.

24. The apparatus of claim 20, wherein said source of carrier gas is heated to a temperature above ambient temperature.

25. The apparatus of claim 20, wherein said source of nanoparticles comprises:
a source of a liquid silane solution;
a droplet generator coupled to the source configured to produce nano or micro scale droplets of solution from the source of liquid silane solution;
a flow channel with a central bore and a reaction zone;
a heating element for heating the reaction zone of the flow channel; and
an input duct coupled to the housing;
wherein droplets moving through the reaction zone of the flow channel are converted to nanoparticles; and
wherein produced nanoparticles are introduced into an interior chamber of the housing through the input duct to be co-deposited on a substrate.

26. A method for synthesizing silicon thin films with embedded Si nanoparticles, comprising:
producing a plurality of nanoparticles;
forming droplets of a liquid silane film composition;
co-depositing the droplets and nanoparticles onto a substrate to form a film; and
heating the deposited film.

27. The method of claim 26, wherein said liquid silane film composition comprises:
at least one liquid silane; and
at least one solvent.

28. The method of claim 27, wherein said liquid silane is a silane selected from the group of silanes consisting of cyclopentasilane (CPS), neopentasilane (NPS), and cyclohexasilane (CHS) and mixtures thereof.

29. The method of claim 27, wherein said solvent is selected from the group of solvents consisting of cyclooctane, hexane and toluene.

30. The method of claim 26, wherein said liquid silane film composition comprises:
at least one liquid silane;
at least one solvent; and
at least one dopant.

31. The method of claim 30, wherein said dopant is a metal dopant selected from the group of dopants consisting of P, B, Sb, Bi, and As.

32. The method of claim 30, wherein said dopant comprises an element selected from the group of elements consisting of Ti, V, Cr Mn, Fe, Co, Ni, Zn, Ga, Ge, Zr, Nb, Mo, Tc, Ru, Rh, Pd, Ag, Cd, In, Sn, Hf, Ta, W, Re, Os, Ir, Pt, Au, Hg, Tl, Pb, Bi and Al.

33. The method of claim 26, wherein said nanoparticles are produced by the process, comprising:
forming droplets of a liquid silane composition;
polymerizing the droplets in a gas phase to produce nanoparticles with heat, laser irradiation or both; and
collecting the polymerized nanoparticles.
